(19) United States
(12) Patent Application Publication
(10) Pub. No.: US 2018/0237917 A1
(43) Pub. Date: Aug. 23, 2018

(54) ELECTROLESS PLATING METHOD AND PRODUCT OBTAINED

(71) Applicant: SEMBLANT LIMITED, Chelsea, Harbour (GB)

(72) Inventors: Gianfranco ARESTA, Hitchin, Hertfordshire (GB); Hennighan GARETH, Bassingbourn (GB); Andrew Simon Hall BROOKS, Melbourn (GB); Sgaukebdra Vikram SINGH, Cambridgeshire (GB)

(21) Appl. No.: 15/751,407

(22) PCT Filed: Aug. 11, 2016
(86) PCT No.: PCT/GB2016/052503

§ 371 Date: Feb. 8, 2018

(30) Foreign Application Priority Data
Aug. 14, 2015 (GB) 1514501.4

(51) Int. Cl. C23C 18/16; C23C 16/04; C23C 16/40; C23C 16/505; C23C 28/04; H05K 3/18; H05K 3/00

(52) U.S. Cl. CPC C23C 18/1605; C23C 16/04; C23C 16/401; C23C 16/505; H05K 2203/095; H05K 3/184; H05K 3/0079; H05K 2203/0713; C23C 28/04

(57) ABSTRACT

The present invention relates to an electroless plating method, in which electroless plating is performed by contacting a substrate which is patterned with an anti-electroless plating coating with an electroless plating solution, whereby metal is deposited by electroless plating onto portions of the substrate that are not patterned with the anti-electroless plating coating, the anti-electroless plating coating having multiple layers, each of which is obtainable by plasma deposition of a precursor mixture comprising (a) one or more organosilicon compounds, (b) optionally O₂, N₂O, NO₂, H₂, NH₃, N₂, SiF⁴ and/or hexafluoropropylene (HFP), and (c) optionally He, Ar and/or Kr.

### FIELD OF THE INVENTION

The present invention relates to an electroless plating method, an anti-electroless plating coating useful in this method, plated substrates, and substrates patterned with the anti-electroless plating coating.

### BACKGROUND TO THE INVENTION

Electroless plating techniques have been known for many decades. Electroless plating is an auto-catalytic method that uses a redox reaction to deposit metal onto a substrate without the passage of an electrical current. Electroless plating generally involves reduction of a complexed metal using a mild reducing agent, such as formaldehyde, with resulting deposition of metal onto the substrate.

For example, silver can be deposited by electroless plating using the following reaction, in which R represents an organic group or hydrogen:

RCHO+2[Ag(NH₃)₂]OH→2Ag+RCOONH4+H₂O+3NH₃

Appropriate chemical reactions can be used to deposit other metals. For example, copper can be deposited by reducing complexed copper with a mild reducing agent, such as formaldehyde, in alkaline solution and in the presence of a palladium catalyst. Nickel is also commonly deposited by electroless plating.

The electroless plating method involves bathing the substrate to be coated in solution containing the reagents necessary to deposit the desired metal. This results in even deposition of the metal over the substrate, including along edges, inside holes and over irregularly shaped objections. Electroless plating can thus be used to deposit metal on substrates with complex structures that would be hard to plate using other techniques, such as electroplating. In most cases, electroless plating involves pre-cleaning, plating, post-cleaning steps, along with several water rinsing steps. Taken together, an electroless plating method generally involves exposure of the substrate to acidic, neutral and basic solution chemistry.

Electroless plating is currently of great interest to the electronics industry, and is of particular interest in the field of microelectromechanical systems (MEMS).

One potential drawback of standard electroless plating techniques is that they generally deposit the metal onto all parts of the substrate exposed to the electroless plating solution. However, depending on the functional requirements of such devices, or assemblies of such devices, selective plating of metal may be desirable. In this regard, it is desirable in some cases to deposit different metals on different parts of the substrate, or only to deposit metal on certain specific areas of the substrate, in order to leave physical structures or features, such as holes, fine screw threads, and the like, un-plated.

There have been a number of attempts to develop effective selective electroless plating techniques.

For example, U.S. Pat. No. 4,681,774 describes application of a sensitizing solution to a substrate, and then removal of that sensitizing solution from areas of the substrate where plating is not desired using laser-etching. When subsequently contacted with a suitable electroless plating solution, metal is only deposited on areas of the substrate coated with the sensitizing solution. The main disadvantage of this technique is that laser-etching process is difficult and time-consuming. Further, this process cannot be carried out on multiple substrates simultaneously.

U.S. Pat. No. 7,891,091 and U.S. Pat. No. 7,923,059 describe techniques in which a substrate is firstly coated unselectively with a layer of conductive material. Further method steps are then carried out in order to deposit further metal selectively by electroless plating. However, in both cases it is necessary as a final step to selectively remove the conductive material that was applied initially. This step is difficult, time-consuming and would generally require fine laser-etching. These processes also cannot be carried out on multiple substrates simultaneously.

There is therefore a need for improved selective electroless plating techniques, which involve simpler and less time-consuming processes that can be carried out in bulk, and ideally avoid laser-etching.

Another potential drawback of standard electroless plating techniques is that some areas of the substrate exposed to the electroless plating solution could be damaged by the alkaline and/or acidic nature of many electroless plating solutions. It would therefore desirable to protect these areas during the electroless plating process.

### SUMMARY OF THE INVENTION

substrates, such that when electroless plating is performed, metal is not deposited on areas of the substrate covered by the anti-electroless plating coating. This allows selective deposition of metal on the substrate. The anti-electroless plating coatings also provide the underlying substrate with high levels of chemical, electrical and physical protection, both before and after electroless plating. Thus, the coating also provides a barrier to any harmful effects, such as etching, erosion or corrosion, which could be caused by the chemicals, for example the acidic/basic solutions and other solvents, used during the electroless plating process. The resulting selective electroless plating process can be carried out in bulk and does not require the use of laser-etching.

Accordingly, the present invention relates to an electroless plating method, in which electroless plating is performed by contacting a substrate which is patterned with an anti-electroless plating coating with an electroless plating solution, whereby metal is deposited by electroless plating onto portions of the substrate that are not patterned with the anti-electroless plating coating, the anti-electroless plating coating having multiple layers, each of which is obtainable by plasma deposition of a precursor mixture comprising (a) one or more organosilicon compounds, (b) optionally O₂, N₂O, NO₂, H₂, NH₃, N₂, SiF₄ and/or hexafluoropropylene (HFP), and (c) optionally He, Ar and/or Kr.

The invention further provides:
a plated substrate obtainable by the method of the invention;
a plated substrate, which substrate is patterned with an anti-electroless plating coating of the invention, and which substrate is plated with metal in areas of the substrate that are not patterned with the anti-electroless plating coating;
a substrate for electroless plating, which substrate is patterned with an anti-electroless plating coating of the invention; and
a method for producing a substrate patterned with an anti-electroless plating coating, which method comprises selectively depositing an anti-electroless plating coating of the invention onto the substrate.

### BRIEF DESCRIPTION OF THE FIGURES

FIGS. 1A to 1C illustrate the selective electroless plating method of the invention.

FIGS. 2 to 4 show cross sections through preferred examples of anti-electroless plating coatings of the invention.

FIG. 5 shows the Fourier transform infrared (FTIR) spectrum for the coating prepared in Example 1.

FIG. 6 shows the FTIR spectrum for the coating prepared in Example 2.

FIG. 7 shows the results from Example 4, in which combs were coated with various multi-layer coatings and then tested for electrical resistance using a liquid (deionised water) drop test. These results demonstrate the ability of the multi-layers tested to act as effective anti-electroless plating coatings.

### DETAILED DESCRIPTION OF THE INVENTION

The present invention is concerned with an electroless plating method, in which a metal is selectively deposited onto specific areas of a substrate. In particular, the substrate on which electroless plating is performed is patterned with an anti-electroless plating coating. As discussed in further detail below, the anti-electroless plating coating of the invention is typically formed by plasma deposition, preferably plasma enhanced chemical vapour deposition (PECVD). The anti-electroless plating coating material prevents deposition of metal in the areas where it is present on the substrate. Metal is thereby selectively deposited onto portions of the substrate that are not patterned with the anti-electroless plating coating.

Electroless plating Electroless plating techniques are well known to those of skill in the art, and rely upon a redox reaction to deposit metal onto a substrate. The chemistry involved in electroless plating is well known to those of skill in the art, and is described in, for example, Electroless Plating: Fundamentals and Applications, Editors: G. O. Mallory, J. B. Hajdu, American Electroplaters and Surface Finishers Society, 1990.

Electroless plating involves contacting the substrate to be coated with an electroless plating solution, which typically contains a complexed metal ion and a reducing agent. A mild reducing agent, such as formaldehyde, is preferably used. The reducing agent reduces the metal ions, thereby to produce the metal which is deposited onto portions of the substrate in contact with the solution.

Electroless plating deposits may be either a pure single elemental metal (<1% impurity or additives), or they may be alloys. Electroless plating is typically used to deposit silver, copper, platinum, gold or nickel. The exact composition of the solution which is contacted with the substrate will depend upon the metal that is to be deposited. A skilled person can readily determine a suitable solution for depositing a given metal. For example:
a typical electroless plating solution for depositing silver comprises complexed silver ions and dimethylamine borane (DMAB) as the reducing agent;
a typical electroless plating solution for depositing copper comprises complexed copper ions and formaldehyde as the reducing agent;
a typical electroless plating solution for depositing platinum or gold comprises complexed platinum or gold ions and a borohydride reducing agent; and
a typical electroless plating solution for depositing nickel or platinum comprises complexed nickel or platinum ions and hydrazine as the reducing agent.

In most cases, electroless plating methods involve acidic and/or basic pre-cleaning steps, along with several subsequent water rinsing steps. Further to that, often post-treatment steps like water rinsing, anti-oxidation or anti-tarnishing and minor backing may also be involved. The electroless plating process as a whole therefore generally involves the substrate being exposed to acidic, neutral and basic chemistries.

Depending on the thickness and the metal/alloy to be deposited, the duration of the electroless plating process may vary from few minutes to more than 60 minutes, excluding the pre- and post electroless plating steps discussed above.

According to the method of the present invention, a substrate which is patterned with an anti-electroless plating coating is used. The anti-electroless plating coating prevents deposition of metal when the substrate is contacted with the electroless plating solution, such that metal is selectively deposited on areas of the substrate that are not patterned with the anti-electroless plating coating.

After electroless plating has been performed and metal has been deposited on areas of the substrate that are not patterned with the anti-electroless plating coating, it is possible either to leave the anti-electroless plating coating in situ or remove it. It is often desirable to leave the anti-electroless plating coating in situ since it can provide the underlying substrate with chemical, electrical and/or physical protection.

It can, however, alternatively be desirable to remove the anti-electroless plating coating after electroless plating has been performed. Removal of the anti-electroless plating coating can be achieved by any suitable technique, such as plasma etching. Plasma etching uses plasma species of fluorocarbons, O₂, N₂, Ar, He and/or their different admixtures, such as fluorocarbon/O₂/Ar or fluorocarbon/Ar/N₂, to remove the anti-electroless plating coating.

Preferably, however, the anti-electroless plating coating is left in situ following electroless plating.

### The Anti-Electroless Plating Coating

The anti-electroless plating coating of the invention comprises multiple layers, each of which is obtainable by plasma deposition of organosilicon compounds. The organosilicon compound(s) can be deposited in the presence or absence of reactive gases and/or non-reactive gases. The resulting layers deposited have general formula SiOₓH_{y}C_{z}FₐN_{b}, wherein the values of x, y, z, a and b depend upon (a) the specific organosilicon compound(s) used, (b) whether or not a reactive gas is present and the identify of that reactive gas, and (c) whether or not a non-reactive gas is present, and the identify of that non-reactive gas. For example, if no fluorine or nitrogen is present in the organosilicon compound(s) and a reactive gas containing fluorine or nitrogen is not used, then the values of a and b will be 0. As will be discussed in further detail below, the values of x, y, z, a and b can be tuned by selecting appropriate organosilicon compound(s) and/or reactive gases, and the properties of each layer and the overall coating controlled accordingly.

For the avoidance of doubt, it will be appreciated that each layer of the anti-electroless plating coating may have organic or inorganic character, depending upon the exact precursor mixture, despite the organic nature of the precursor mixtures used to form those layers. In an organic layer of general formula SiOₓH_{y}C_{z}FₐN_{b}, the values of y and z will be greater than zero, whereas in an inorganic layer of general formula SiOₓH_{y}C_{z}FₐN_{b} the values of y and z will tend towards zero. The organic nature of a layer can easily be determined by a skilled person using routine analytical techniques, such as by detecting the presence of carbon-hydrogen and/or carbon-carbon bonds using spectroscopic techniques well known to those skilled in the art. For example, carbon-hydrogen bonds can be detected using Fourier transform infrared spectroscopy. Similarly, the inorganic nature of a layer can easily be determined by a skilled person using routine analytical techniques, such as by detecting the absence of carbon-hydrogen and/or carbon-carbon bonds using spectroscopic techniques well known to those skilled in the art. For example, the absence of carbon-hydrogen bonds can be assessed using Fourier transform infrared spectroscopy.

### Plasma Deposition Process

The layers present in the anti-electroless plating coatings of the invention are obtainable by plasma deposition, typically plasma enhanced chemical vapour deposition (PECVD) or plasma enhanced physical vapour deposition (PEPVD), preferably PECVD, of a precursor mixture. The plasma deposition process is typically carried out at a reduced pressure, typically 0.001 to 10 mbar, preferably 0.01 to 1 mbar, for example about 0.7 mbar. The deposition reactions occur in situ on the surface of the electrical assembly, or on the surface of layers that have already been deposited.

Plasma deposition is typically carried out in a reactor that generates plasma which comprises ionized and neutral feed gases/precursors, ions, electrons, atoms, radicals and/or other plasma generated neutral species. A reactor typically comprises a chamber, a vacuum system, and one or more energy sources, although any suitable type of reactor configured to generate plasma may be used. The energy source may include any suitable device configured to convert one or more gases to a plasma. Preferably the energy source comprises a heater, radio frequency (RF) generator, and/or microwave generator.

Plasma deposition results in a unique class of materials which cannot be prepared using other techniques. Plasma deposited materials have a highly disordered structure and are generally highly cross-linked, contain random branching and retain some reactive sites. These chemical and physical distinctions are well known and are described, for example in Plasma Polymer Films, Hynek Biederman, Imperial College Press 2004 and Principles of Plasma Discharges and Materials Processing, 2^{nd} Edition, Michael A. Lieberman, Alan J. Lichtenberg, Wiley 2005.

Typically, the substrate to which the anti-electroless plating coating is to be applied is placed in the chamber of a reactor and a vacuum system is used to pump the chamber down to pressures in the range of 10⁻³ to 10 mbar. One or more gases is typically then injected (at controlled flow rate) into the chamber and an energy source generates a stable gas plasma. One or more precursor compounds is typically then be introduced, as gases and/or vapours, into the plasma phase in the chamber. Alternatively, the precursor compound may be introduced first, with the stable gas plasma generated second. When introduced into the plasma phase, the precursor compounds are typically decomposed (and/or ionized) to generate a range of active species (i.e. radicals) in the plasma that is deposited onto and forms a layer on the exposed surface of electrical assembly.

The exact nature and composition of the material deposited typically depends on one or more of the following conditions (i) the plasma gas selected; (ii) the particular precursor compound(s) used; (iii) the amount of precursor compound(s) [which may be determined by the combination of the pressure of precursor compound(s), the flow rate and the manner of gas injection]; (iv) the ratio of precursor compound(s); (v) the sequence of precursor compound(s); (vi) the plasma pressure; (vii) the plasma drive frequency; (viii) the power pulse and the pulse width timing; (ix) the coating time; (x) the plasma power (including the peak and/or average plasma power); (xi) the chamber electrode arrangement; and/or (xii) the preparation of the incoming assembly.

Typically the plasma drive frequency is 1 kHz to 4 GHz. Typically the plasma power density is 0.001 to 50 W/cm², preferably 0.01 W/cm² to 0.02 W/cm², for example about 0.0175 W/cm². Typically the mass flow rate is 5 to 1000 sccm, preferably 5 to 20 sccm, for example about 10 sccm. Typically the operating pressure is 0.001 to 10 mbar, preferably 0.01 to 1 mbar, for example about 0.7 mbar. Typically the coating time is 10 seconds to >60 minutes, for example 10 seconds to 60 minutes.

Plasma processing can be easily scaled up, by using a larger plasma chamber. However, as a skilled person will appreciate, the preferred conditions will be dependent on the size and geometry of the plasma chamber. Thus, depending on the specific plasma chamber that is being used, it may be beneficial for the skilled person to modify the operating conditions.

### Precursor Compounds

The anti-electroless plating coatings of the invention comprise layers which are obtainable by plasma deposition of a precursor mixture. The precursor mixture comprises one or more organosilicon compounds, and optionally further comprises a reactive gas (such as O₂) and/or a non-reactive gas (such as Ar). The resulting layers deposited have general formula SiOₓH_{y}C_{z}FₐN_{b}, wherein the values of x, y, z, a and b depend upon (i) the specific organosilicon compound(s) used, and (ii) whether or not a reactive gas is present and the identify of that reactive gas.

Typically the precursor mixture consists, or consists essentially, of the one or more organosilicon compounds, the optional reactive gas(es) and the optional non-reactive gas(es). As used herein, the term “consists essentially of” refers to a precursor mixture comprising the components of which it consists essentially as well as other components, provided that the other components do not materially affect the essential characteristics of the resulting layer formed from the precursor mixture. Typically, a precursor mixture consisting essentially of certain components will contain greater than or equal to 95 wt % of those components, preferably greater than or equal to 99 wt % of those components.

When the one or more organosilicon compounds are plasma deposited in the absence of an excess of oxygen and nitrogen-containing reactive gas (such as NH₃, O₂, N₂O or NO₂), the resulting layer will be organic in nature and will be of general formula SiOₓH_{y}C_{z}FₐN_{b}. The values of y and z will be greater than 0. The values of x, a and b will be greater than 0 if O, F or N is present in the precursor mixture, either as part of the organosilicon compound(s) or as a reactive gas.

When the one or more organosilicon compounds are plasma deposited in the presence of oxygen-containing reactive gas (such as O₂ or N₂O or NO₂), the hydrocarbon moieties in the organosilicon precursor react with the oxygen-containing reactive gas to form CO₂ and H₂O. This will increase the inorganic nature of the resulting layer. If sufficient oxygen-containing reactive gas is present, all of the hydrocarbon moieties maybe removed, such that resulting layer is substantially inorganic/ceramic in nature (in which in the general formula SiOₓH_{y}C_{z}FₐN_{b}, y, z, a and b will have negligible values tending to zero). The hydrogen content can be reduced further by increasing RF power density and decreasing plasma pressure, thus enhancing the oxidation process and leading to a dense inorganic layer (in which in the general formula SiOₓH_{y}C_{z}FₐN_{b}, x is as high as 2 with y, z, a and b will have negligible values tending to zero).

Typically, the precursor mixture comprises one organosilicon compound, but it may be desirable under some circumstances to use two or more different organosilicon compounds, for example two, three or four different organosilicon compounds.

Typically, the organosilicon compound is an organosiloxane, an organosilane, a nitrogen-containing organosilicon compound such as a silazane or an aminosilane, or a halogen-containing organosilicon compound such as a halogen-containing organosilane. The organosilicon compound may be linear or cyclic.

The organosilicon compound may be a compound of formula (I):

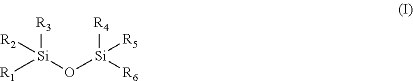

wherein each of R₁ to R₆ independently represents a C₁-C₆ alkyl group, a C₂-C₆ alkenyl group or hydrogen, provided that at least one of R₁ to R₆ does not represent hydrogen. Preferably, each of R₁ to R₆ independently represents a C₁-C₃ alkyl group, a C₂-C₄ alkenyl group or hydrogen, for example methyl, ethyl, vinyl, allyl or hydrogen, provided that at least one of R₁ to R₆ does not represent hydrogen. Preferably at least two or three, for example four, five or six, of R₁ to R₆ do not represent hydrogen. Preferred examples include hexamethyldisiloxane (HMDSO), tetramethyldisiloxane (TMDSO), 1,3-divinyltetramethyldisiloxane (DVTMDSO) and hexavinyldisiloxane (HVDSO). Hexamethyldisiloxane (HMDSO) and tetramethyldisiloxane (TMDSO) are particularly preferred, with hexamethyldisiloxane (HMDSO) most preferred.

Alternatively, the organosilicon compound may be a compound of formula (II):

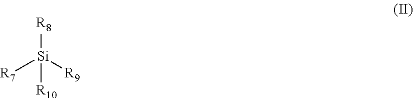

wherein each of R₇ to R₁₀ independently represents a C₁-C₆ alkyl group, a C₁-C₆ alkoxy group, a C₂-C₆ alkenyl group, hydrogen, or a —(CH₂)₁₋₄NR′R″ group in which R′ and R″ independently represent a C₁-C₆ alkyl group, provided that at least one of R₇ to R₁₀ does not represent hydrogen. Preferably each of R₇ to R₁₀ independently represents a C₁-C₃ alkyl group, C₁-C₃ alkoxy group, a C₂-C₄ alkenyl group, hydrogen or a —(CH₂)₂₋₃NR′R″ group in which R′ and R″ independently represent a methyl or ethyl group, for example methyl, ethyl, isopropyl, methoxy, ethoxy, vinyl, allyl, hydrogen or —CH₂CH₂CH₂N(CH₂CH₃)₂, provided that at least one of R₇ to R₁₀ does not represent hydrogen. Preferably at least two, for example three or four, of R₇ to R₁₀ do not represent hydrogen. Preferred examples include allyltrimethylsilane, allyltrimethoxysilane (ATMOS), tetraethylorthosilicate (TEOS), 3-(diethylamino) propyl-trimethoxysilane, trimethylsilane (TMS) and triisopropylsilane (TiPS).

Alternatively, the organosilicon compound may be a cyclic compound of formula (III):

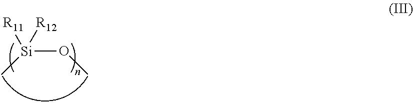

wherein n represents 3 or 4, and each of R₁₁ and R₁₂ each independently represents a C₁-C₆ alkyl group, a C₂-C₆ alkenyl group or hydrogen, provided that at least one of R₁₁ and R₁₂ does not represent hydrogen. Preferably, each of R₁₁ and R₁₂ independently represents a C₁-C₃ alkyl group, a C₂-C₄ alkenyl group or hydrogen, for example methyl, ethyl, vinyl, allyl or hydrogen, provided that at least one of R₁₁ and R₁₂ does not represent hydrogen. Preferred examples include trivinyl-trimethyl-cyclotrisiloxane (V₃D₃), tetravinyl-tetramethyl-cyclotetrasiloxane (V₄D₄), tetramethylcyclotetrasiloxane (TMCS) and octamethylcyclotetrasiloxane (OMCTS).

Alternatively, the organosilicon compound may be a compound of formula (IV):

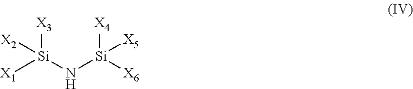

wherein each of X₁ to X₆ independently represents a C₁-C₆ alkyl group, a C₂-C₆ alkenyl group or hydrogen, provided that at least one of X₁ to X₆ does not represent hydrogen. Preferably each of X₁ to X₆ independently represents a C₁-C₃ alkyl group, a C₂-C₄ alkenyl group or hydrogen, for example methyl, ethyl, vinyl, allyl or hydrogen, provided that at least one of X₁ to X₆ does not represent hydrogen. Preferably at least two or three, for example four, five or six, of X₁ to X₆ do not represent hydrogen. A preferred example is hexamethyldisilazane (HMDSN).

Alternatively, the organosilicon compound may be a cyclic compound of formula (V):

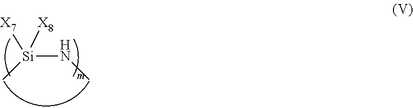

wherein m represents 3 or 4, and each of X₇ and X₈ independently represents a C₁-C₆ alkyl group, a C₂-C₆ alkenyl group or hydrogen, provided that at least one of X₇ and Xs does not represent hydrogen. Preferably, each of X₇ and X₈ independently represents a C₁-C₃ alkyl group, a C₂-C₄ alkenyl group or hydrogen, for example methyl, ethyl, vinyl, allyl or hydrogen, provided that at least one of X₇ and X₈ does not represent hydrogen. A preferred example is 2,4,6-trimethyl-2,4,6-trivinylcyclotrisilazane.

Alternatively, the organosilicon compound may be a compound of formula (VI):

Hₐ(X⁹)_{b}Si(N(X¹⁰)₂)_{4-a-b} (VI)

wherein X⁹ and X¹⁰ independently represent C₁-C₆ alkyl groups, a represents 0, 1 or 2, b represents 1, 2 or 3, and the sum of a and b is 1, 2 or 3. Typically, X⁹ and X¹⁰ represent a C₁-C₃ alkyl group, for example methyl or ethyl. Preferred examples are dimethylamino-trimethylsilane (DMATMS), bis(dimethylamino)dimethylsilane (BDMADMS) and tris(dimethylamino)methylsilane (TDMAMS).

Alternatively, the organosilicon compound may be a compound of formula (VII):

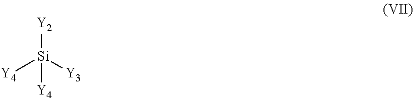

wherein each of Y₁ to Y₄ independently represents a C₁-C₈ haloalkyl group, a C₁-C₆ alkyl group, C₁-C₆ alkoxy group, or a C₂-C₆ alkenyl group or hydrogen, provided that at least one of Y₁ to Y₄ represents a C₁-C₈ haloalkyl group. Preferably, each of Y₁ to Y₄ independently represents a C₁-C₃ alkyl group, C₁-C₃ alkoxy group, a C₂-C₄ alkenyl group or a C₁-C₈ haloalkyl group, for example methyl, ethyl, methoxy, ethoxy, vinyl, allyl, trifluoromethyl or 1H,1H,2H,2H-perfluorooctyl, provided that at least one of Y₁ to Y₄ represents a haloalkyl group. Preferred examples are trimethyl(trifluoromethyl)silane and 1H,1H,2H,2H-perfluorooctyltriethoxysilane.

Preferably the organosilicon compound is hexamethyldisiloxane (HMDSO), tetramethyldisiloxane (TMDSO), 1,3-divinyltetramethyldisiloxane (DVTMDSO), hexavinyldisiloxane (HVDSO allyltrimethylsilane, allyltrimethoxysilane (ATMOS), tetraethylorthosilicate (TEOS), 3-(diethylamino)propyl-trimethoxysilane, trimethylsilane (TMS), triisopropylsilane (TiPS), trivinyl-trimethyl-cyclotrisiloxane (V₃D₃), tetravinyl-tetramethyl-cyclotetrasiloxane (V₄D₄), tetramethylcyclotetrasiloxane (TN/ICS), octamethylcyclotetrasiloxane (OMCTS), hexamethyldisilazane (HMDSN), 2,4,6-trimethyl-2,4,6-trivinylcyclotrisilazane, dimethylamino-trimethylsilane (DMATMS), bis(dimethylamino)dimethylsilane, (BDMADMS), tris(dimethylamino)methylsilane (TDMAMS), trimethyl(trifluoromethyl)silane or 1H,1H,2H,2H-perfluorooctyltriethoxysilane. Hexamethyldisiloxane (HMDSO) and tetramethyldisiloxane (TMDSO) are particularly preferred, with hexamethyldisiloxane (HMDSO) most preferred.

As used herein, the term C₁-C₆ alkyl embraces a linear or branched hydrocarbon groups having 1 to 6, preferably 1 to 3 carbon atoms. Examples include methyl, ethyl, n-propyl and i-propyl, butyl, pentyl and hexyl.

As used herein, the term C₂-C₆ alkenyl embraces a linear or branched hydrocarbon groups having 2 or 6 carbon atoms, preferably 2 to 4 carbon atoms, and a carbon-carbon double bond. Preferred examples include vinyl and allyl.

As used herein, a halogen is typically chlorine, fluorine, bromine or iodine and is preferably chlorine, bromine or fluorine, most preferably fluorine.

As used herein, the term C₁-C₆ haloalkyl embraces a said C₁-C₆ alkyl substituted by one or more said halogen atoms. Typically, it is substituted by 1, 2 or 3 said halogen atoms. Particularly preferred haloalkyl groups are —CF₃ and —CCl₃.

As used herein, the term C₁-C₆ alkoxy group is a said alkyl group which is attached to an oxygen atom. Preferred examples include methoxy, ethoxy, propoxy, isopropoxy, butoxy, isobutoxy, tert-butoxy, pentoxy and hexoxy.

The precursor mixture optionally further comprises a reactive gas. The reactive gas is selected from O₂, N₂O, NO₂, H₂, NH₃, N₂, SiF₄ and/or hexafluoropropylene (HFP). These reactive gases are generally involved chemically in the plasma deposition mechanism, and so can be considered to be co-precursors. O₂, N₂O and NO₂ are oxygen-containing co-precursors, and are typically added in order to increase the inorganic character of the resulting layer deposited. This process is discussed above. N₂O and NO₂ are also nitrogen-containing co-precursors, and are typically added in order to increase additionally the nitrogen content of the resulting layer deposited (and consequently the value of b in the general formula SiOₓH_{y}C_{z}FₐN_{b} is increased).

H₂ is a reducing co-precursor, and is typically added in order to reduce the oxygen content (and consequently the value of x in the general formula SiOₓH_{y}C_{z}FₐN_{b}) of the resulting layer deposited. Under such reducing conditions, the carbon and hydrogen are also generally removed from the resulting layer deposited (and consequently the values of y and z in the general formula SiOₓH_{y}C_{z}FₐN_{b} are also reduced). Addition of H₂ as a co-precursor increases the level of cross-linking in the resulting layer deposited.

N₂ is a nitrogen-containing co-precursor, and is typically added in order to increase the nitrogen content of the resulting layer deposited (and consequently the value of b in the general formula SiOₓH_{y}C_{z}FₐN_{b} is increased).

NH₃ is also a nitrogen-containing co-precursor, and so is typically added in order to increase the nitrogen content of the resulting layer deposited (and consequently the value of b in the general formula SiOₓH_{y}C_{z}FₐN_{b} is increased). However, NH₃ additionally has reducing properties. As with the addition of H₂, this means that when NH₃ is used as a co-precursor, oxygen, carbon and hydrogen are generally removed from the resulting layer deposited (and consequently the values of x, y and z in the general formula SiOₓH_{y}C_{z}FₐN_{b} are reduced). Addition of NH₃ as a co-precursor increases the level of cross-linking in the resulting layer deposited. The resulting layer tends towards a silicon nitride structure.

SiF₄ and hexafluoropropylene (HFP) are fluorine-containing co-precursors, and typically added in order to increase the fluorine content of the resulting layer deposited (and consequently the value of a in the general formula SiOₓH_{y}C_{z}FₐN_{b} is increased).

A skilled person can easily adjust the ratio of reactive gas to organosilicon compound(s) at any applied power density, in order to achieve the desired modification of the resulting layer deposited.

The precursor mixture also optionally further comprises a non-reactive gas. The non-reactive gas is He, Ar or Kr. The non-reactive gas is not involved chemically in the plasma deposition mechanism, but does generally influence the physical properties of the resulting material. For example, addition of He, Ar or Kr will generally increase the density of the resulting layer, and thus its hardness. Addition of He, Ar or Kr also increases cross-linking of the resulting deposited material.

### Structure and Properties of the Anti-Electroless Plating Coating

The anti-electroless plating coating of the invention comprises at least two layers. The first, or lowest layer, in the anti-electroless plating coating is in contact with the surface of the substrate. The final, or uppermost layer, in the anti-electroless plating coating is in contact with the environment. When the anti-electroless plating coating comprises more than two layers, then those additional layers will be located between the first/lowest and final/uppermost layers.

Typically, the anti-electroless plating coating comprises from two to ten layers. Thus, the multilayer coating may have two, three, four, five, six, seven, eight, nine or ten layers. Preferably, the anti-electroless plating coating has from two to eight layers, for example from two to six layers, or from three to seven layers, or from four to eight layers.

The boundary between each layer may be discrete or graded. In an anti-electroless plating coating that has more than two layers, each boundary between layers may be either discrete or graded. Thus, all of the boundaries may be discrete, or all of the boundaries may be graded, or there may be both discrete and graded boundaries with the coating.

A graded boundary between two layers can be achieved by switching gradually over time during the plasma deposition process from the precursor mixture required to form the first of the two layers to the precursor mixture required to form the second of the two layers. The thickness of the graded region between the two layers can be adjusted by altering the time period over which the switch from the first precursor mixture to the second precursor mixture occurs. Under some circumstances graded boundaries can be advantageous, as the adhesion between layers is generally increased by a graded boundary.

A discrete boundary between two layers can be achieved by switching immediately during the plasma deposition process from the precursor mixture required to form the first of the two layers to the precursor mixture required to form the second of the two layers.

Different layers are deposited by varying the precursor mixture and/or the plasma deposition conditions in order to obtain layers which have the desired properties. The properties of each individual layer are selected such that the resulting multi-layer coating has the desired properties.

For the avoidance of doubt, all layers of the anti-electroless plating coating of the invention are obtainable by plasma deposition of precursor mixtures as herein defined which contain one or more organosilicon compounds. Thus, the anti-electroless plating coatings of the invention do not contain other layers which are not obtainable from precursor mixtures as herein defined, such as metallic or metal oxide layers.

### Properties of First/Lowest Layer

It is generally desirable for the anti-electroless plating coating to show good adhesion, both to the surface of the substrate and between layers within the coating. This is desirable so that the anti-electroless plating coating is robust during use. Adhesion can be tested using tests known to those skilled in the art, such as a Scotch tape test or a scratch adhesion test.

It is preferable, therefore, that the first/lowest layer of the anti-electroless plating coating, which is in contact with the substrate, is formed from a precursor mixture that results in a layer that adheres well to that substrate. The exact precursor mixture that is required will depend upon the specific material(s) from which the substrate is made, and a skilled person will be able to adjust the precursor mixture accordingly. However, layers which are organic in character typically adhere best to the surface of the substrate. Layers which contain no, or substantially no, fluorine also typically adhere best to the surface of the substrate.

Typically, therefore, the first/lowest layer of the anti-electroless plating coating is organic. A layer with organic character can be achieved by using a precursor mixture that contains no, or substantially no, oxygen-containing reactive gas (i.e. no, or substantially no, or O₂, N₂O or NO₂). It is thus preferable that the first/lowest layer of the anti-electroless plating coating is deposited using a precursor mixture that contains no, or substantially no, O₂, N₂O or NO₂.

As used herein, the reference to a precursor mixture containing “substantially no” specified component(s) refers to a precursor mixture that may contain trace amounts of the specified component(s), provided that the specified component(s) do not materially affect the essential characteristics of the resulting layer formed from the precursor mixture. Typically, therefore a precursor mixture that contains substantially no specified component(s) contains less than 5 wt % of the specified component(s), preferably less than 1 wt % of the specified component(s), most preferably less than 0.1 wt % of the specified component(s).

A layer which contains no, or substantially no, fluorine can be achieved by using a precursor mixture that contains no, or substantially no, fluorine-containing organosilicon compound and no, or substantially no, fluorine-containing reactive gas (ie. no, or substantially no, SiF₄ or HFP). It is thus preferable that the first/lowest layer of the anti-electroless plating coating is deposited using a precursor mixture that contains no, or substantially no, fluorine-containing organosilicon compound, SiF₄ or HFP.

Accordingly, it is particularly preferred that the first/lowest layer of the anti-electroless plating coating is deposited using a precursor mixture that contains no, or substantially no, O₂, N₂O, NO₂, fluorine-containing organosilicon compound, SiF₄ or HFP. The resulting coating will be organic in character and contain no fluorine, and so will adhere well to the surface of the substrate.

It is also generally desirable for the first/lowest layer of the anti-electroless plating coating to be capable of absorbing any residual moisture present on the substrate prior to deposition of the coating. The first/lowest layer will then generally retain the residual moisture within the coating, and thereby reduce the nucleation of corrosion and erosion sites on the substrate.

### Properties of the Final/Uppermost Layer

It is generally desirable for the final/uppermost layer of the anti-electroless plating coating, that is to say the layer that is exposed to the environment, to be anti-corrosive and chemically stable, and thus resistant to immersion in acidic or basic solutions, or solvents such as acetone, ethanol, methanol or isopropyl alcohol (IPA). These are the conditions to which a substrate is exposed during a typical electroless plating process. It is thus preferred that the final/uppermost layer of the anti-electroless plating coating has high chemical resistance.

The chemical resistance of a layer or coating can be readily determined by a skilled person. For example, the techniques described below in the Examples can be used, in which the layer/coating is wiped with the test solution/solvent and then immersed in the test solution/solvent, which inspection of the integrity of the layer/coating after each step. Suitable test solutions/solvents include acidic and basic solutions at different pH, typically an electroless plating solution with or without the complex metal ions present. Integrity of the layer/coating can be checked by any suitable means, such as via inspection under microscope, FT-IR analysis or thickness reduction after immersion in solutions. Alternatively or additionally, the effectiveness of a layer/coating can be checked by inspecting (typically via optical methods such as microscopy) whether metal was deposited in areas coated by the anti-electroless plating coating following electroless plating.

For the Si-based material in the present invention, a layer with organic character will typically show high levels of chemical resistance coupled with hydrophobicity. Organic character can be achieved by using a precursor mixture that contains no, or substantially no, oxygen-containing reactive gas (i.e. no, or substantially no, or O₂, N₂O or NO₂). Typically, therefore, the final/uppermost layer of the anti-electroless plating coating is organic. It is thus preferable that the final/uppermost layer of the anti-electroless plating coating is deposited using a precursor mixture that contains no, or substantially no, O₂, N₂O or NO₂. The pre-cursor mixture may optionally contain a halogen-containing organosilicon compound, SiF₄ and/or HFP, thereby increasing the fluorine-content of the layer, which typically further increases chemical resistance.

It is also generally desirable for the final/uppermost layer of the anti-electroless plating coating to be hydrophobic. Hydrophobicity can be determined by measuring the water contact angle (WCA) using standard techniques. Typically, the WCA of the final/uppermost layer of the multi-layer coating is >90°, preferably from 95° to 115°, more preferably from 100° to 110°.

The hydrophobicity of a layer can be modified by adjusting the precursor mixture. For example, a layer which has organic character will generally be hydrophobic. As noted above, a layer with organic character can be achieved, for example, by using a precursor mixture that contains no, or substantially no, oxygen-containing reactive gas (i.e. no, or substantially no, or O₂, N₂O or NO₂). As discussed above, if an oxygen-containing gas is present a significant amount in the precursor mixture, the organic character and thus hydrophobicity of the resulting layer will be reduced. It is thus preferable that the final/uppermost layer of the anti-electroless plating coating is deposited using a precursor mixture that contains no, or substantially no, O₂, N₂O or NO₂.

The hydrophobicity of a layer can also be increased by using a halogen-containing organosilicon compound, such as the compounds of formula VII defined above. With such a precursor, the resulting layer will contain halogen atoms and will generally be hydrophobic. Halogen atoms can also be introduced by including SiF₄ or HFP as a reactive gas in the precursor mixture, which will result in the inclusion of fluorine in the resulting layer. It is thus preferable that the final/uppermost layer of the anti-electroless plating coating is deposited using a precursor mixture that comprises a halogen-containing organosilicon compound, SiF₄ and/or HFP, typically in addition to the components discussed above for achieving organic character.

It is also generally desirable for the final/uppermost layer of the anti-electroless plating coating to be oleophobic. Generally, a layer that is hydrophobic will also be oleophobic. This is particularly the case for fluorine-containing coatings. Thus, if the water contact angle (WCA) of the final/uppermost layer of the anti-electroless plating coating is greater than 100°, then the coating will be oleophobic. A WCA of greater than 105° is preferred for increased oleophobic properties.

It is also generally desirable for the final/uppermost layer of the anti-electroless plating coating to have a hardness of at least 0.5 GPa, preferably at least 1 GPa, more preferably at least 2 GPa, most preferably at least 4 GPa. The hardness is typically no greater than 11 GPa. Hardness can be measured by nanohardness tester techniques known to those skilled in the art. The hardness of a layer can be modified by adjusting the precursor mixture, for example to include a non-reactive gas such as He, Ar and/or Kr. This results in a layer which is denser and thus harder. It is thus preferably that the final/uppermost layer of the anti-electroless plating coating is deposited using a precursor mixture that comprises He, Ar and/or Kr.

It is also possible to adjust the hardness by modifying the plasma deposition conditions. Thus, reducing the pressure at which deposition occurs generally results in a layer which is denser and thus harder. Increasing the RF power generally results in a layer which is denser and thus harder. These conditions and/or the precursor mixture can be readily adjusted to achieve a desired hardness as set out above.

It will be appreciated from the above discussion that it is generally preferred that the final/uppermost layer of the anti-electroless plating coating is not inorganic, since the properties of such coatings are generally less favourable than coatings in which the final/uppermost layer is organic. When the anti-electroless plating coating has two or three layers, it is particularly preferred that the final/uppermost layer is not inorganic (ie. the final/uppermost layer is organic). However, when the anti-electroless plating coating contains four or more layers, the differences in properties between coatings with an inorganic final/uppermost layer and coatings with an organic final/uppermost layer are generally less significant, and indeed it can be desirable to have a final/uppermost layer that is not organic under those circumstances to provide increased hardness.

### Moisture Barrier Properties

It is desirable for the anti-electroless plating coating to act as a moisture barrier, so that electroless plating solution cannot breach the coating and damage the underlying substrate. The moisture barrier properties of the anti-electroless plating coating can be assessed by measuring the water vapour transmission rate (WVTR) using standard techniques, such as a MOCON test. Typically, the WVTR of the anti-electroless plating coating is from 10 g/m²/day down to 0.001 g/m²/day.

Typically, the moisture barrier properties of the anti-electroless plating coating may be enhanced by inclusion of at least one layer which has a WVTR of from 0.5 g/m²/day down to 0.1 g/m²/day. This moisture barrier layer is typically not the first/lowest or final/uppermost layer of the anti-electroless plating coating. Several moisture barrier layers may be present in the anti-electroless plating coating, each of which may have the same or different composition.

Generally, layers which are substantially inorganic in character and contain very little carbon are the most effective moisture barriers. Such layers can be obtained by, for example, plasma deposition of a precursor mixture that comprises an organosilicon compound and an oxygen-containing reactive gas (ie. O₂, N₂O or NO₂). Addition of a non-reactive gases such as He, Ar or Kr, use of a high RF power density and/or reducing the plasma pressure will also assist in forming a layer with good moisture barrier properties.

It is therefore preferred that at least one layer of the anti-electroless plating coating is obtainable by plasma deposition of a precursor mixture comprising an organosilicon compound and O₂, N₂O and/or NO₂, and preferably also He, Ar and/or Kr. Preferably the precursor mixture consists, or consists essentially, of these components.

A layer containing nitrogen atoms will also typically have desirable moisture barrier properties. Such a layer can be obtained by using a nitrogen-containing organosilicon compound, typically a silazane or aminosilane precursor, such as the compounds of formula (IV) to (VI) defined above. Nitrogen atoms can also be introduced by including N₂, NO₂, N₂O or NH₃ as a reactive gas in the precursor mixture. Preferably the precursor mixture consists, or consists essentially, of these components.

It is therefore also preferred that at least one layer of the anti-electroless plating coating is obtainable by plasma deposition of a precursor mixture comprising a nitrogen-containing organosilicon compound, N₂, NO₂, N₂O and/or NH₃. Preferably the precursor mixture consists, or consists essentially, of these components.

### Other Properties

The thickness of the anti-electroless plating coating of the present invention will depend upon the number of layers that are deposited, and the thickness of each layer deposited.

Typically, the first/lowest layer and the final/uppermost layer have a thickness of from 0.05 μm to 5 μm. Typically, any layers present between the first/lowest layer and the final/uppermost layer have a thickness of from 0.1 μm to 5 μm.

The overall thickness of the anti-electroless plating coating is of course dependent on the number of layers, but is typically from 0.1 μm to 20 μm, preferably from 0.1 μm to 5 μm.

The thickness of each layer can be easily controlled by a skilled person. Plasma processes deposit a material at a uniform rate for a given set of conditions, and thus the thickness of a layer is proportional to the deposition time. Accordingly, once the rate of deposition has been determined, a layer with a specific thickness can be deposited by controlling the duration of deposition.

The thickness of the anti-electroless plating coating and each constituent layer may be substantially uniform or may vary from point to point, but is preferably substantially uniform.

Thickness may be measured using techniques known to those skilled in the art, such as a profilometry, reflectometry or spectroscopic ellipsometry.

Adhesion between layers of the anti-electroless plating coating can be improved, where necessary, by introducing a graded boundary between layers, as discussed above. Graded boundaries are particularly preferred for layers which contain fluorine, since these tend to exhibit poor adhesion. Thus, if a given layer contains fluorine, it preferably has a graded boundary with the adjacent layer(s).

Alternatively, where necessary, discrete layers within the anti-electroless plating coating can be chosen such that they adhere well to the adjacent layers within the coating.

The Substrate and Patterning Thereof with the Anti-Electroless Plating Coating

The substrate can be part of any object, or the whole of any object, onto which it is desirable to deposit metal by electroless plating.

Electroless plating has been used for many decades to provide a hard, corrosion resistant surface finish to engineering components. Its application has been extended to the electronics industry for the production of solderable surfaces on printed circuit boards, where the use of flip-chip technology has required the development of low-cost methods for solder bumping of semiconductor wafers. Recently, electroless plating has also been utilized in the creation of microelectronics, such as microelectromechanical systems. The substrate used in the electroless plating technique of the invention may therefore be metal or plastic, for example as part of a printed circuit board, or a MEMS device or electronic chip.

The substrate is contacted with the electroless plating solution during the electroless plating method. Thus, part of the object, or the whole of the object, onto which it is desirable to deposit metal by electroless plating is contacted with the electroless plating solution during the electroless plating method.

Prior to conducting the electroless plating technique of the invention, it is necessary to first deposit the anti-electroless plating coating onto the substrate. The substrate is patterned with the anti-electroless plating coating, such that the areas of the substrate where it is desired for metal to be deposited remain uncoated, whilst areas of the substrate where deposition of metal is undesirable and/or unnecessary are coated.

A substrate patterned with the anti-electroless plating coating of the invention can be prepared in a number of different ways. For example, a mask can be applied to the substrate prior to plasma deposition of the anti-electroless plating coating. The masks that are used in a gas-based plasma deposition technique are much easier to apply than the masks that are required in a traditional liquid-based deposition technique. The mask can then be removed after plasma deposition is complete, leaving the substrate patterned with the anti-electroless plating coating. Alternatively, the anti-electroless plating coating could be applied unselectively to the entire substrate, and then selectively removed, leaving the substrate patterned with the anti-electroless plating coating. Selective removal can be achieved by any suitable technique, such as plasma etching.

### DETAILED DESCRIPTION OF THE FIGURES

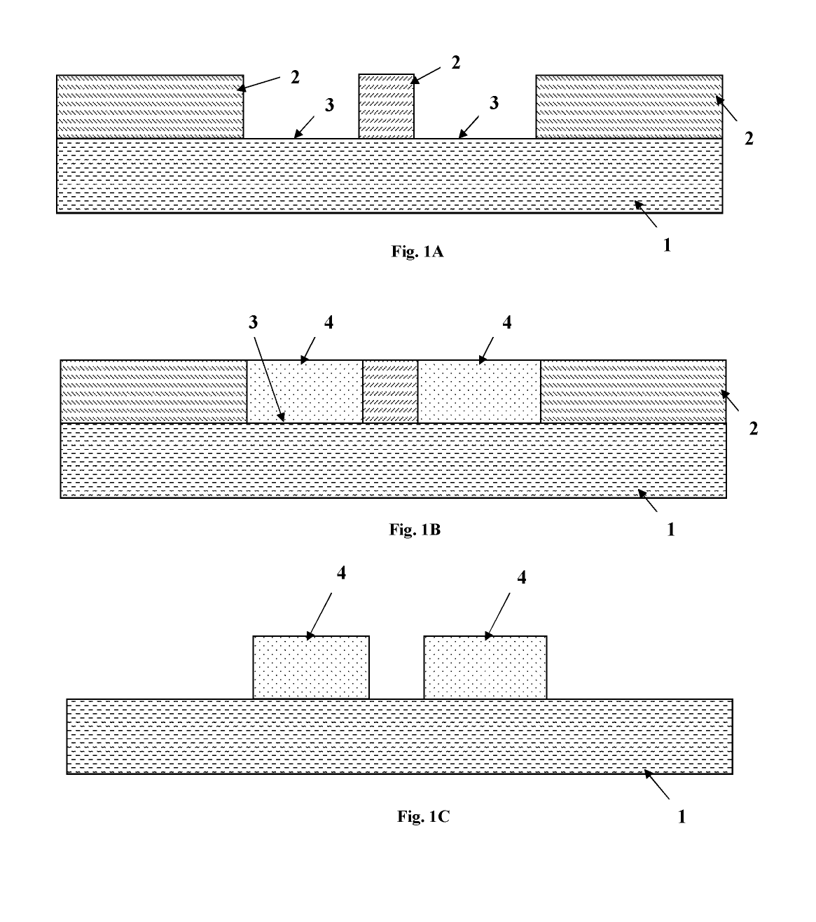

Aspects of the invention will now be described with reference to the embodiment shown in FIGS. 1 to 4, in which like reference numerals refer to the same or similar components.

FIGS. 1A to 1C illustrate the selective electroless plating method of the invention. FIG. 1A depicts a substrate 1 for electroless plating, which substrate is patterned with anti-electroless plating coating 2. Portions 3 of the substrate are not patterned with the anti-electroless plating coating. The patterned substrate is then contacted with an electroless plating solution, and the resulting plated substrate is depicted in FIG. 1B. In FIG. 1B metal 4 is deposited by electroless plating onto portions 3 of the substrate 1 that are not patterned with the anti-electroless plating coating 2. FIG. 1B thus depicts a plated substrate, which substrate 1 is patterned with an anti-electroless plating coating 2, and which substrate is plated with metal 4 in areas 3 of the substrate 1 that are not patterned with the anti-electroless plating coating 2. Although anti-electroless plating coating 2 is generally left in situ following electroless plating, since it provides protection to the underlying substrate, it is also possible to remove anti-electroless plating coating 2 after electroless plating has been performed. FIG. 1C depicts the resulting plated substrate, in which the metal 4 remains plating the substrate, whilst anti-electroless plating coating 2 is absent following its removal.

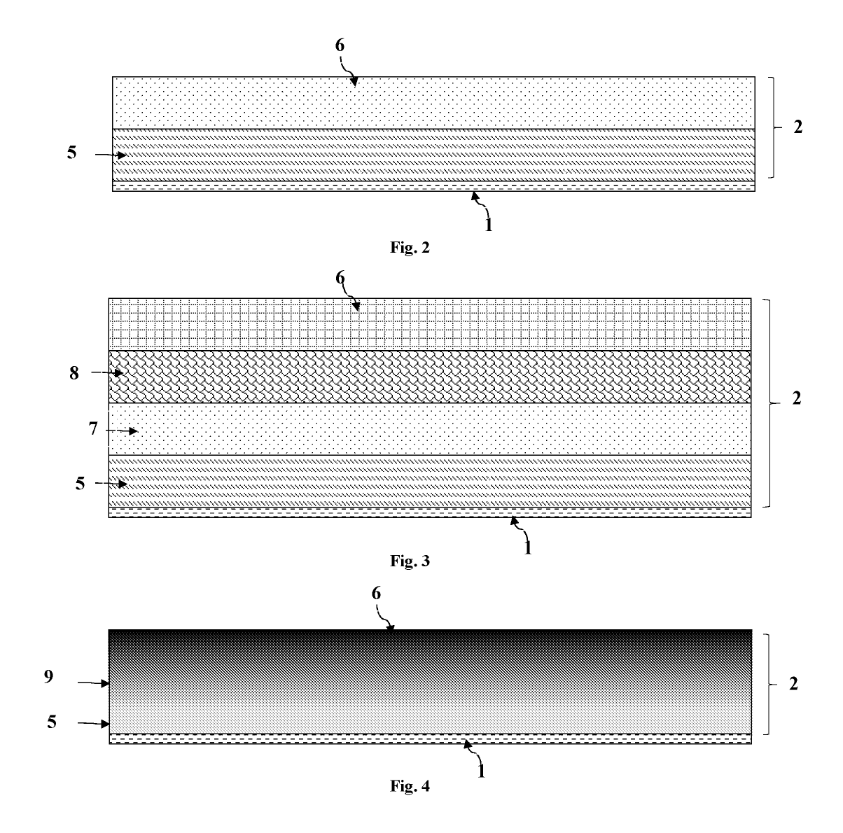

FIG. 2 shows a cross section through a preferred example of the anti-electroless plating coating 2 in FIG. 1. The anti-electroless plating coating 2 has a first/lowest layer 5 which is in contact with substrate 1, and a final/uppermost layer 6. This anti-electroless plating coating 2 has two layers 5 and 6, and the boundary between the layers 5 and 6 is discrete.

FIG. 3 shows a cross section through another preferred example of the anti-electroless plating coating 2 in FIG. 1. The anti-electroless plating coating 2 has a first/lowest layer 5 which is in contact with substrate 1, and a final/uppermost layer 6. Between layers 5 and 6 are two further layers 7 and 8. This anti-electroless plating coating 2 has four layers 5, 6, 7, and 8, and the boundary between the layers 5, 6, 7, and 8 is discrete.

FIG. 4 shows a cross section through another preferred example of the anti-electroless plating coating 2 in FIG. 1. The anti-electroless plating coating 2 has a first/lowest layer 5 which is in contact with the substrate 1, and a final/uppermost layer 6. This anti-electroless plating coating 2 has two layers 5 and 6, and the boundary 9 between layers 5 and 6 is graded.

### EXAMPLES

Aspects of the invention will now be described with reference to the Examples below.

### Example 1—Deposition of a Single SiOₓC_{y}H_{z} Layer

A substrate was placed into a plasma-enhanced chemical vapour deposition (PECVD) deposition chamber, and the pressure was then brought to <10⁻³ mbar. He was injected at a flow rate resulting in a chamber pressure of 0.480 mbar, then it was increased (by means of a throttle valve) to 0.50 mbar. Plasma was ignited at RF power density of 0.573 W cm⁻² for 3-5 seconds. Next, HMDSO was injected into the chamber at a flow rate of 6 sccm and RF power density was at 0.225, 0.382, 0.573 or 0.637 Wcm⁻² for 20 minutes. Pressure was kept (through a throttle valve) at 0.5 mbar during the deposition process.

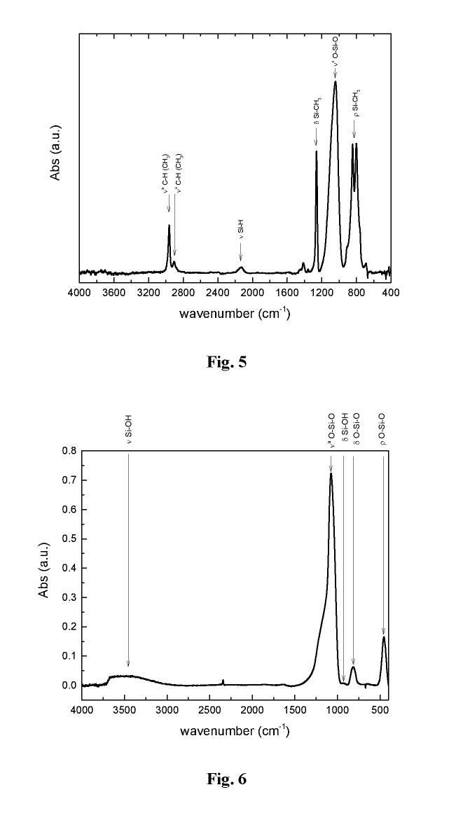

Polymeric organosilicon SiOₓC_{y}H_{z} layers were obtained on the substrate. The FT-IR transmission spectra for the layer obtained using an RF power density of 0.637 Wcm⁻² is shown in FIG. 5.

The SiOₓC_{y}H_{z} layers showed hydrophobic character with a WCA (water contact angle) of ˜100°.

Layers deposited at 0.637 Wcm⁻² as described were tested for chemical resistance against organic solvents (namely isopropyl alcohol [IPA] and acetone) and aqueous acid and basic solutions. The acid solutions were aqueous HCl solutions with the following pHs: 6; 5; 4; 3; 2; and 1. The basic solutions were aqueous NaOH with the following pHs: 8; 9; 10; 11; 12; and 13.

The layers were wiped first with the above-mentioned solvents and solutions by rubbing a cotton bud (wet with the solvents/solutions) on the surface of the layer. The layers were secondly immersed in the above-mentioned solvents and solutions. In both tests, the layers did not show any signs of delamination, scratching or damage.

Electrical assemblies have been also coated with the above described layers in order to test their electric resistance/H₂O barrier properties. The coated substrates (combs and pads) were immersed into deionized (DI) water and 5 V were applied into the circuit. The results are set out in Table 1 below.

TABLE 1

| RF | Thickness | Electrical feature | | | | | |
|---|---|---|---|---|---|---|---|
| power | of | Comb A | Comb A′ | Comb B′ | Comb B | Pads | Pads′ |
| density | coating | R (Ω) at | R (Ω) at | R (Ω) at | R (Ω) at | R (Ω) at | R (Ω) at |
| (Wcm⁻²) | (nm) | 1′ | 1′ | 1′ | 1′ | 1′ | 1′ |
| 0.225 | 550 | 5.56E+08 | 3.00E+08 | 1.72E+08 | 7.63E+07 | 6.98E+10 | 1.25E+10 |
| 0.382 | 680 | 1.61E+07 | 4.56E+07 | 1.93E+07 | 4.05E+07 | 9.00E+09 | 2.93E+12 |
| 0.573 | 1170 | 1.61E+07 | 4.56E+07 | 1.93E+07 | 4.05E+07 | 9.00E+09 | 2.93E+12 |
| 0.637 | 1260 | 1.56E+08 | 1.02E+08 | 1.16E+08 | 6.99E+07 | 3.53E+10 | 3.37E+12 |

### Example 2—Deposition of Single SiOₓH_{z} Layer

A substrate was placed into a PECVD deposition chamber, and the pressure was then brought to <10⁻³ mbar. Against this base pressure, O₂ was inject up to 0.250 mbar of chamber pressure. After that, He was injected in order to reach a chamber pressure of 0.280 mbar. Finally, HMDSO was injected at a flow rate of 2.5 sccm and pressure was increased (by means of throttle valve) to 0.300 mbar. Plasma was then ignited with a power density of 0.892 Wcm⁻² and the process was continued until the desired thickness of approximate 750 nm was achieved. A SiOₓH_{z} layer was obtained with FT-IR transmission spectrum as shown in FIG. 6. The SiOₓH_{z} layer showed hydrophilic character with a WCA 50°.

The SiOₓH_{z} layers were tested for chemical resistance as described in Example 1, and again passed both tests.

### Example 3—Deposition of SiOₓC_{y}H_{z}/SiOₓH_{z} Multilayer

The experimental conditions leading to the PECVD deposition of the SiOₓC_{y}H_{z}/SiOₓH_{z} multilayers on substrates were basically the same as described in Examples 1 and 2. Briefly, SiOₓC_{y}H_{z} was deposited with the same procedure explained in Example 1 (RF power density used for this experiment was 0.637 Wcm⁻²), then chamber was brought to vacuum (<10⁻³ mbar) and the deposition of SiOₓH_{z}, on top of the SiOₓC_{y}H_{z} layer, was performed according to the procedure explained in Example 2. Then, a second SiOₓC_{y}H_{z} layer was deposited on top of the SiOₓH_{z} layer. The thickness of the second SiOₓC_{y}H_{z} layer was half that of the first SiOₓC_{y}H_{z} layer. This was achieved by halving the deposition time. These steps resulted in multilayer coating with the structure: SiOₓC_{y}H_{z}/SiOₓH_{z}/SiOₓC_{y}H_{z}.

The process was then repeated on some substrates in order to add a second pair of SiOₓC_{y}H_{z}/SiOₓH_{z} layer, thereby giving the structure: SiOₓC_{y}H_{z}/SiOₓH_{z}/SiOₓC_{y}H_{z}/SiOₓH_{z}/SiOₓC_{y}H_{z}.

Both multilayers were tested for chemical resistance as described in Example 1, and again passed both tests.

Substrates coated with these two multilayers were tested for electrical resistance while immersed into DI water by applying 5 V into the circuit. The results are listed in Table 2 below.

TABLE 2

| | Electrical feature | | | | | |
|---|---|---|---|---|---|---|
| | Comb A | Comb A′ | Comb B′ | Comb B | Pads | Pads′ |
| Multilayer | R (Ω) at | R (Ω) at | R (Ω) at | R (Ω) at | R (Ω) at | R (Ω) at |
| structure | 1′ | 1′ | 1′ | 1′ | 1′ | 1′ |
| SiOₓC_{y}H_{z}/SiOₓH_{z}/ | 6.48E+08 | 2.03E+08 | 2.39E+10 | 1.71E+09 | 8.66E+11 | 1.55E+12 |
| SiOₓC_{y}H_{z} | | | | | | |
| SiOₓC_{y}H_{z}/SiOₓH_{z}/ | 2.57E+10 | 6.64E+10 | 5.24E+09 | 8.15E+09 | 1.78E+12 | 1.43E+12 |
| SiOₓC_{y}H_{z}/SiOₓH_{z}/ | | | | | | |
| SiOₓC_{y}H_{z} | | | | | | |

The performances of the multilayers were tested also the following way. A 5V potential was applied across the coated electrical assemblies, which were immersed in a sweat solution. A failure was recorded when the current leakage across the coating reached 50 μA. The results are set out below in Table 3

TABLE 3

| | Electrical feature | | | |
|---|---|---|---|---|
| | Comb A | Comb B | Pads | Pads′ |
| | Time to | Time to | Time to | Time to |
| Multilayer | failure | failure | failure | failure |
| structure | (min) | (min) | (min) | (min) |
| SiOₓC_{y}H_{z}/SiOₓH_{z}/ | 6.9 | 19.9 | 6.9 | 6.95 |
| SiOₓC_{y}H_{z} | | | | |
| SiOₓC_{y}H_{z}/SiOₓH_{z}/ | 65.7 | 32.9 | 291.4 | 327.1 |
| SiOₓC_{y}H_{z}/SiOₓH_{z}/ | | | | |
| SiOₓC_{y}H_{z} | | | | |

### Example 4—Assessment of Properties of Coatings

Conformal coatings were deposited onto combs under the conditions set out below.

### 1. Deposition Conditions for SiOₓ Coating

Against a base pressure of 10⁻³ mbar, O₂ was inject up to 0.250 mbar of chamber pressure. After that, He was injected in order to reach a chamber pressure of 0.280 mbar. HMDSO was added at flow rate of 2.5 sccm. Pressure was set to 0.280 mbar. Plasma was ignited at a power density of 0.892 Wcm⁻².

2. Deposition Conditions for SiOₓC_{y}H_{z} Coating

Against a base pressure of 10⁻³ mbar, He was injected at a flow rate resulting in a chamber pressure of 0.480 mbar, then the pressure was increased (by means of a throttle valve) to 0.50 mbar. Plasma was ignited at RF power density of 0.573 Wcm⁻² for 3-5 seconds. Next, HMDSO was injected into the chamber at a flow rate of 6 sccm together and RF power density of 0.637 Wcm⁻².

3. Deposition Conditions for SiOₓC_{y}H_{z}/SiOₓ Coating

An SiOₓC_{y}H_{z} layer was deposited as described in paragraph 2 above. Then the deposition chamber was evacuated and the SiOₓ layer was deposited on top of the SiOₓC_{y}H_{z} layer as described in paragraph 1 above.

4. Deposition Conditions for SiOₓC_{y}H_{z}/SiOₓ/SiOₓC_{y}H_{z} Coating

An SiOₓC_{y}H_{z} layer was deposited as described in paragraph 2 above. Then the deposition chamber was evacuated and the SiOₓ coating was deposited on top of the SiOₓC_{y}H_{z} layer with the same conditions as described in paragraph 1 above (except for the fact that HMDSO and He mixture was injected and RF plasma was ignited directly at a power density of 0.637 Wcm⁻²). Finally, the deposition chamber was evacuated and a second SiOₓC_{y}H_{z} layer was deposited on top of the SiOₓ layer with the conditions described in paragraph 2 above.

5. Deposition of SiOₓC_{y}H_{z}/SiOₓH_{y}C_{z}N_{b}/SiOₓC_{y}H_{z}/SiOₓH_{y}C_{z}N_{b}/SiOₓC_{y}H_{z} Coating

The SiOₓC_{y}H_{z} layers were deposited by mixing 17.5 sccm of HMDSO with 20 sccm of Ar at a RF power density of 0.057 Wcm⁻², while the SiOₓH_{y}C_{z}N_{b} layers were deposited by mixing 17.5 sccm of HMDSO with 15 sccm of N₂O at a RF power density of 0.057 Wcm⁻².

6. Deposition Conditions for SiOₓH_{y}C_{z}Fₐ Layer

A SiOₓC_{y}H_{z}Fₐ layer was deposited by mixing 17.5 sccm of HMDSO with 20 sccm of HPF at a RF power density of 0.057 Wcm⁻².

The coated combs were then tested as follows. Water was placed on the coated combs and power was then applied across the poles of the coated combs. Electrical resistance was measured over time, with a high resistance indicating that the coating was intact and that no current was following. As soon as the coating started leaking water, current started to pass between the poles of the component and resistance decreased. Coating failure was deemed to have occurred when resistance fell below 10⁸Ω.

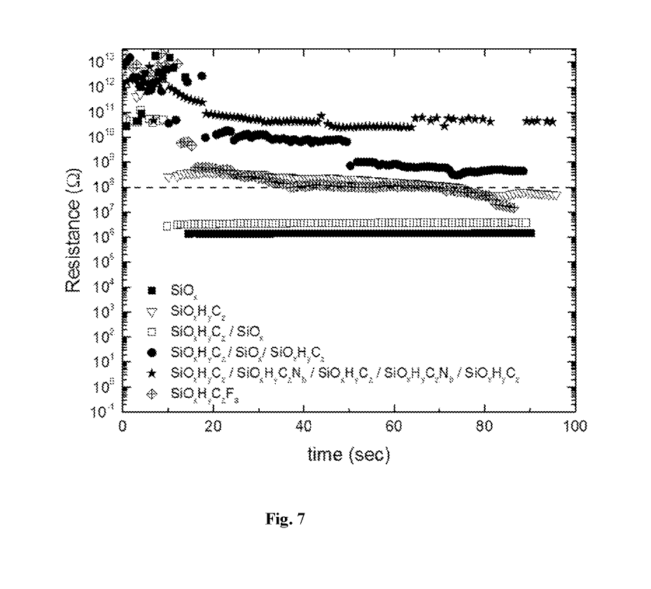

The results of this test are depicted in FIG. 7. The SiOₓC_{y}H_{z}/SiOₓ/SiOₓC_{y}H_{z} coating performed well (see the black circles), with a high resistance throughout the duration of the test. The SiOₓC_{y}H_{z}/SiOₓH_{y}C_{z}N_{b}/SiOₓC_{y}H_{z}/SiOₓH_{y}C_{z}N_{b}/SiOₓC_{y}H_{z} also performed well (see the black stars), with an even higher resistance throughout the duration of the test. The three single layer coatings (SiOₓ [black squares], SiOₓC_{y}H_{z} [unshaded triangles] and SiOₓH_{y}C_{z}Fₐ [diamonds]) failed, with resistance either starting below 10⁸Ω (for the SiOₓ layer) or decreasing to under 10⁸Ω during the duration of the test (for the SiOₓC_{y}H_{z} and SiOₓH_{y}C_{z}Fₐ layers).

The SiOₓC_{y}H_{z}/SiOₓ two layers coating (unshaded squares) also failed in this test, performing less well than the SiOₓC_{y}H_{z} single layer coating. It was notable that addition of a further SiOₓC_{y}H_{z} layer on top of the SiOₓC_{y}H_{z}/SiOₓ coating greatly improved its performance as discussed above. It is believed that whilst a SiOₓ layer as the top layer of the coating may result in reduced performance under some conditions for coatings with low numbers of layers (such as SiOₓC_{y}H_{z}/SiOₓ), such a reduction in performance is unlikely to be observed when there are higher number of layers in the coating.

1. An electroless plating method, in which electroless plating is performed by contacting a substrate which is patterned with an anti-electroless plating coating with an electroless plating solution, whereby metal is deposited by electroless plating onto portions of the substrate that are not patterned with the anti-electroless plating coating,
the anti-electroless plating coating having multiple layers, each of which is obtainable by plasma deposition of a precursor mixture comprising (a) one or more organosilicon compounds, (b) optionally O₂, N₂O, NO₂, H₂, NH₃, N₂, SiF₄ and/or hexafluoropropylene (HFP), and (c) optionally He, Ar and/or Kr.

2. The method according to claim 1, wherein the anti-electroless plating coating has two to ten layers, preferably four to eight layers.

3. The method according to claim 1 or 2, wherein the plasma deposition is plasma enhanced chemical vapour deposition (PECVD).

4. The method according to any one of the preceding claims, wherein the plasma deposition occurs at a pressure of 0.001 to 10 mbar.

5. The method according to any one of the preceding claims, wherein the first/lowest layer of the anti-electroless plating coating, which is in contact with the substrate, is organic.

6. The method according to claim 5, wherein the first/lowest layer of the anti-electroless plating coating is obtainable by plasma deposition of a precursor mixture containing no, or substantially no, O₂, N₂O or NO₂.

7. The method according to claim 6, wherein the first/lowest layer of the anti-electroless plating coating is obtainable by plasma deposition of a precursor mixture containing no, or substantially no, O₂, N₂O, NO₂, fluorine-containing organosilicon compound, SiF₄ or HFP.

8. The method according to any one of the preceding claims, wherein the final/uppermost layer of the anti-electroless plating coating is obtainable by plasma deposition of a precursor mixture containing no, or substantially no, O₂, N₂O or NO₂.

9. The method according to any one of the preceding claims, wherein the final/uppermost layer of the anti-electroless plating coating is obtainable by plasma deposition of a precursor mixture comprising one or more halogen-containing organosilicon compounds, SiF₄ and/or HFP.

10. The method according to any one of the preceding claims, wherein the final/uppermost layer of the multi anti-electroless plating coating is obtainable by plasma deposition of a precursor mixture comprising He, Ar and/or Kr.

11. The method according to any one of the preceding claims, wherein at least one layer of the anti-electroless plating coating is a moisture barrier layer obtainable by plasma deposition of a precursor mixture comprising O₂, N₂O and/or NO₂

12. The method according to any one of the preceding claims, wherein at least one layer of the anti-electroless plating coating is a moisture barrier layer obtainable by plasma deposition of a precursor mixture comprising a nitrogen-containing organosilicon compound, N₂, NO₂, N₂O and/or NH₃.

13. The method assembly according to claim 11 or 12, wherein the precursor mixture from which the at least one moisture barrier layer is obtainable further comprises He, Ar and/or Kr.

14. The method according to any one of claims 11 to 13, wherein the at least one moisture barrier is located between the first/lowest layer and the final/uppermost layer of the anti-electroless plating coating.

15. The method according to any one of the preceding claims, wherein the one or more organosilicon compounds from which each layer of the anti-electroless plating coating is obtainable by plasma deposition is independently selected from hexamethyldisiloxane (HMDSO), tetramethyldisiloxane (TMDSO), 1,3-divinyltetramethyldisiloxane (DVTMDSO), hexavinyldisiloxane (HVDSO) allyltrimethylsilane, allyltrimethoxysilane (ATMOS), tetraethylorthosilicate (TEOS), trimethylsilane (TMS), triisopropylsilane (TiPS), trivinyl-trimethyl-cyclotrisiloxane (V₃D₃), tetravinyl-tetramethyl-cyclotetrasiloxane (V₄D₄), tetramethylcyclotetrasiloxane (TMCS), octamethylcyclotetrasiloxane (OMCTS), hexamethyldisilazane (HMDSN), 2,4,6-trimethyl-2,4,6-trivinylcyclotrisilazane, dimethylamino-trimethylsilane (DMATMS), bis(dimethylamino)dimethylsilane, (BDMADMS), tris(dimethylamino)methylsilane (TDMAMS), trimethyl(trifluoromethyl)silane or 1H,1H,2H,2H-perfluorooctyltriethoxysilane, 3-(Diethylamino)propyl-trimethoxysilane.

16. The method according to any one of the preceding claims, in which the anti-electroless plating coating is removed after electroless plating has been performed.

17. The method according to claim 16, wherein the anti-electroless plating coating is removed by plasma etching.

18. A plated substrate obtainable by the method as defined in any one of claims 1 to 17.

19. A plated substrate, which substrate is patterned with an anti-electroless plating coating as defined in any one of claims 1 to 15, and which substrate is plated with metal in areas of the substrate that are not patterned with the anti-electroless plating coating.

20. A substrate for electroless plating, which substrate is patterned with an anti-electroless plating coating as defined in any one of claims 1 to 15.

21. A method for producing a substrate patterned with an anti-electroless plating coating, which method comprises selectively depositing an anti-electroless plating coating as defined in any one of claims 1 to 15 onto the substrate.
